(19) United States
(12) Patent Application Publication
(10) Pub. No.: US 2008/0182395 A1
(43) Pub. Date: Jul. 31, 2008

(54) METHOD FOR FORMING PATTERN IN SEMICONDUCTOR DEVICE

(75) Inventors: Chang-Heon PARK, Ichon-shi (KR); Dong-Ryeol Lee, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 11/967,201

(22) Filed: Dec. 30, 2007

(30) Foreign Application Priority Data
Jan. 30, 2007 (KR) 10-2007-0000408

(51) Int. Cl. H01L 21/283

(52) U.S. Cl. 438/589; 257/E21.159

(57) ABSTRACT

A method for fabricating a dual polysilicon gate includes providing a substrate, forming a gate oxide layer over the substrate, forming a polysilicon layer over the gate oxide layer, patterning the polysilicon layer in a condition of applying a relatively low first pressure or a relatively high first bias power, thereby forming gate patterns and exposing a given portion of the gate oxide layer, and forming an oxide layer over the exposed given portion of the gate oxide layer by using a plasma oxidation process while performing an over-etch process on the gate patterns in a condition of applying a second pressure higher than the first pressure or a second bias power lower than the first bias power.

### CROSS-REFERENCE TO RELATED APPLICATIONS

The present invention claims priority to Korean patent application number 2007-0000408, filed on Jan. 3, 2007, which is incorporated by reference in its entirety.

### BACKGROUND OF THE INVENTION

The present invention relates to a method for fabricating a semiconductor device, and more particularly, to a method for forming a dual polysilicon gate in the semiconductor device.

Recently, as semiconductor devices become highly integrated, the size of devices gets reduced. Thus, a semiconductor device having a structure including both a P-type metal oxide silicon (PMOS) transistor and an N-type MOS transistor generally employs a dual polysilicon gate including a polysilicon for a gate electrode doped with impurities whose type is identical to a channel type. By using the dual polysilicon gate, it is possible to reduce a short channel effect (SCE) and increase an operating speed of the device.

The method for forming the dual polysilicon gate is briefly described, hereinafter. A gate oxide layer is formed over a substrate including an isolation layer. A polysilicon layer for a gate electrode is formed over the gate oxide layer.

N-type impurities are selectively ion implanted into the polysilicon layer in the NMOS region and P-type impurities are selectively ion implanted into the polysilicon layer in the PMOS region. The polysilicon layer with the N-type impurities in the NMOS region is an ‘N-doped polysilicon layer’. The polysilicon layer with the P-type impurities in the PMOS region is a ‘P-doped polysilicon layer’.

An annealing process is performed to activate the impurities in the polysilicon layer and masking and etching processes are performed to pattern a gate so that an N-doped polysilicon gate is formed in the NMOS region and a P-doped polysilicon gate is formed in the PMOS region.

However, a typical method for forming a dual polysilicon gate has problems described below.

When simultaneously etching the N-doped polysilicon layer and the P-doped polysilicon layer to pattern the gate, a profile gap between polysilicon gate patterns in the NMOS and the PMOS regions is generated. Since the N-doped polysilicon layer and P-doped polysilicon layer are crystallized by the annealing process, a subsequent etch process is difficult to perform. Thus, adjusting the gate profile is getting more difficult.

A method for decreasing the gap profile between the N-doped polysilicon gate pattern and the P-doped polysilicon gate pattern is required. The method easily decreases the profile gap by easily etching the N-doped polysilicon layer and the P-doped polysilicon layer.

### SUMMARY OF THE INVENTION

Embodiments of the present invention are directed to provide a method for forming a dual polysilicon gate in a semiconductor device.

The dual polysilicon gate in the semiconductor device prevents a profile gap between gate patterns by augmenting a physical effect when etching an N-doped polysilicon layer and a P-doped polysilicon layer. The N-doped polysilicon gate and the P-doped polysilicon gate have a vertical profile.

The dual polysilicon gate in the semiconductor device also compensates a damage of the gate oxide layer when a physical effect increases during etching the N-doped polysilicon layer and the P-doped polysilicon layer.

In accordance with an aspect of the present invention, there is provided a method for fabricating a dual polysilicon gate. The method includes providing a substrate, forming a gate oxide layer over the substrate, forming a polysilicon layer over the gate oxide layer, patterning the polysilicon layer in a condition of applying a relatively low first pressure or a relatively high first bias power, thereby forming gate patterns and exposing a given portion of the gate oxide layer, and forming an oxide layer over the exposed given portion of the gate oxide layer by using a plasma oxidation process while performing an over-etch process on the gate patterns in a condition of applying a second pressure higher than the first pressure or a second bias power lower than the first bias power.

### BRIEF DESCRIPTION OF THE DRAWINGS

FIGS. 1A to 1C are cross-sectional views of a method for forming a dual polysilicon gate in accordance with an embodiment of the present invention.

### DESCRIPTION OF SPECIFIC EMBODIMENTS

The present invention relates to a method for forming a dual polysilicon gate in a semiconductor device.

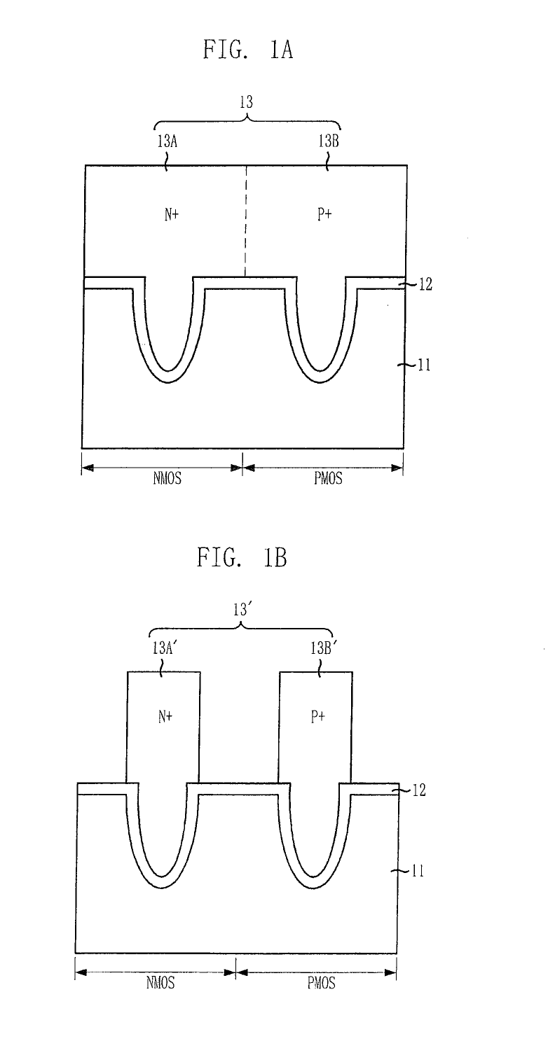

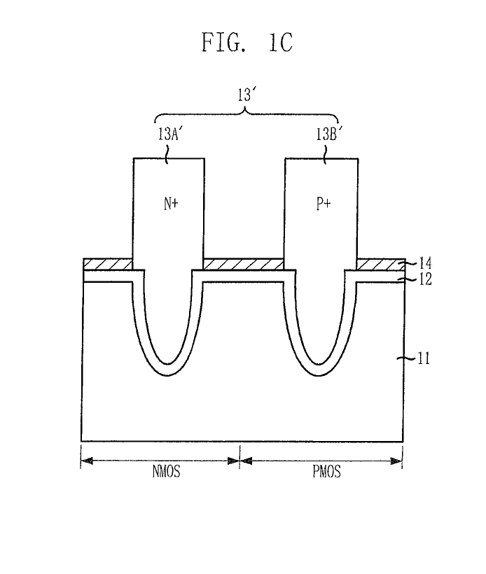

FIGS. 1A to 1C are cross-sectional views of a method for forming a dual polysilicon gate in accordance with an embodiment of the present invention. An NMOS region and a PMOS region are illustrated together to improve understanding.

Referring to FIG. 1A, a gate oxide layer 12 is formed over a substrate 11. The substrate 11 may have a recess to increase a transistor channel length. In this case, the gate oxide layer 12 is formed over the whole surface of the substrate 11 including the recess.

A polysilicon layer for a gate electrode is formed over the gate oxide layer 12. N-type impurities are selectively ion implanted into the polysilicon layer in the NMOS region and P-type impurities are selectively ion-implanted into the polysilicon layer in the PMOS region. The polysilicon layer in the NMOS region is an N-doped polysilicon layer 13A and the polysilicon layer in the PMOS region is a P-doped polysilicon layer 13B. The polysilicon layer including the N-doped polysilicon layer 13A and the P-doped polysilicon layer 13B is a doped polysilicon layer 13.

Then, the doped polysilicon layer 13 is crystallized by activating impurities in the doped polysilicon layer 13 through an annealing process.

Referring to FIG. 1B, the doped polysilicon layer 13 is patterned through masking and etching processes to form a polysilicon pattern 13′. In detail, a certain photoresist pattern (not shown) is formed over the doped polysilicon layer 13. The doped polysilicon layer 13 is etched using the photoresist pattern as an etch mask to form the polysilicon pattern 13′, i.e., a gate pattern. The polysilicon pattern in the NMOS region 13A′ is an N-doped polysilicon gate and the polysilicon pattern in the PMOS region 13B′ is a P-doped polysilicon gate.

To easily etch the doped polysilicon layer 13 (i.e., the N-doped polysilicon layer 13A and the P-doped polysilicon layer 13B) and to form gate patterns having a vertical profile so as to decrease a profile gap between the gate patterns in the NMOS region and the PMOS region, the doped polysilicon layer 13 is etched while increasing a physical effect. To increase the physical effect, the etching process is performed by applying a low pressure, e.g., lower than approximately 50 mTorr. Meanwhile, the etching process is performed by applying a bias power, e.g., higher than approximately 80 W. In this case, a source power of approximately 70 W to approximately 150 W can be applied. A gas including helium oxide (HeO) or helium (He) is used as an etch gas. Thus, the vertical profile of the gate pattern is easily secured and a reactant generated during etching the doped polysilicon layer 13 can be minimized. Furthermore, a small molecular weight decreases a damage of the gate oxide layer 12 due to a physical etch.

When performing the etching process while increasing the physical effect, the gate oxide layer 12 may be damaged. When the gate oxide layer 12 is damaged, a device characteristic is deteriorated. Thus, a method for minimizing the damage of the gate oxide layer 12 during the physical etching process is required. To minimize the damage of the gate oxide layer 12, it is preferable to etch the doped polysilicon layer 13 until the gate oxide layer 12 is exposed.

In addition, the etching process is performed in two steps. In the first step, the etching process is performed on the doped polysilicon layer 13 by applying a relatively low pressure in the low pressure range, e.g., approximately 10 mTorr, to have a strong physical etch characteristic and a high etch rate. In the second step where gate oxide layer 12 is exposed, the physical etch characteristic is reduced to decrease the etch rate compared with in the first step. Thus, in the second step, the etching process is performed by applying a relatively high pressure in the low pressure range, e.g., approximately 50 mTorr.

In the first step, a gas mixture of HeO and hydro bromide (HBr) is used as an etch gas. An etch ending point of this etch process is set based on an etch degree of an isolation pattern, e.g., a peripheral region.

In the second step, the doped polysilicon layer 13 is etched using a gas mixture of oxygen (O₂), He, and HBr as an etch gas until the gate oxide layer 12 in a region where a dense pattern is formed, e.g., a cell region, is exposed.

By performing the first and the second etch steps, it is possible to form the N-doped polysilicon pattern and the P-doped polysilicon pattern having a vertical profile and decrease the profile gap between patterns.

However, since the etch process is performed until the gate oxide layer 12 is exposed to prevent the damage of the gate oxide layer 12, a bottom portion of the doped polysilicon layer 13 nay remain un-etched, so that a bridge can be generated between gates. Thus, it is preferable to perform an additional process illustrated in FIG. 5C.

Referring to FIG. 1C, an over-etch process is performed on the polysilicon pattern 13′ to prevent the generation of the bridge between gates and, at the same time, an oxide layer 14 is formed over the gate oxide layer 12 by a plasma oxidation process to compensate the damage of the gate oxide layer 12 due to the over-etch process.

The polysilicon pattern 13′ may be over-etched by applying a pressure or a bias power respectively higher or lower than that in the etching process of the polysilicon layer 13 in FIG. 1B. Applying the higher pressure or lower bias power minimizes the physical effect and increases the plasma oxidation degree, so that the damage of the gate oxide layer 12 is prevented. Desirably, the pressure used in the over-etch process is more than 30 mTorr higher than that used in the etch process of the polysilicon layer 13. The bias power used in the over-etch process is more than 50 W lower than that used in the etch process of the polysilicon layer 13 in FIG. 1B. Therefore, in another embodiment, the bias power applied in the over-etch process may be 0 W. That is, the over-etch and the oxidation processes are performed by only applying a source power without supplying the bias. A gas mixture of O₂, He, and HBr is used as an etch gas during the over-etch process performed in the high pressure or the low bias power. A large amount of the O₂ gas is used and a hydrogen (H₂) gas can be added to increase the plasma oxidation degree. Also, the over-etch and the plasma oxidation processes are performed in a high temperature, e.g., higher than approximately 80° C. An O₂ flushing process may be performed during the above process.

The over-etch and the plasma oxidation processes performed on the polysilicon pattern 13′ preferably performed by in-situ process while performing the etch process on the doped polysilicon layer 13 (refer to FIG. 1B).

Through the processes illustrated in FIGS. 1A to 1C, the polysilicon gate pattern in the NMOS region, i.e., the N-doped polysilicon pattern 13A′, and the polysilicon gate pattern in the PMOS region, i.e., the P-doped polysilicon pattern 13B′, have a vertical profile. Thus, the profile gap between patterns is reduced and the damage of the gate oxide layer 12 is minimized, improving a device characteristic.

In accordance with the present invention, the polysilicon layer is etched to the polysilicon gate pattern having a vertical profile. Thus, the profile gap between gate patterns in the NMOS region and the PMOS region decreases and the damage of the gate oxide layer is also prevented, so that a device characteristic is improved.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a dual polysilicon gate, the method comprising:
providing a substrate;
forming a gate oxide layer over the substrate;
forming a polysilicon layer over the gate oxide layer;
patterning the polysilicon layer in a condition of applying a relatively low first pressure or a relatively high first bias power, thereby forming gate patterns and exposing a given portion of the gate oxide layer; and
forming an oxide layer over the exposed given portion of the gate oxide layer by using a plasma oxidation process while performing an over-etch process on the gate patterns in a condition of applying a second pressure higher than the first pressure or a second bias power lower than the first bias power.

2. The method of claim 1, wherein patterning the polysilicon layer is performed until the given portion of the gate oxide layer is exposed.

3. The method of claim 1, wherein patterning the polysilicon layer is performed by using a gas including helium (He) or helium oxide (HeO).

4. The method of claim 1, wherein the first pressure is lower than approximately 50 mTorr.

5. The method of claim 1, wherein the first bias power is higher than approximately 80 W.

6. The method of claim 1, wherein the over-etch and the plasma oxidation processes are performed by using a gas mixture of He, HBr, and oxygen (O₂).

7. The method of claim 6, wherein the gas mixture further includes a hydrogen (H₂) gas.

8. The method of claim 1, wherein the over-etch and the plasma oxidation processes are performed at a temperature higher than approximately 80° C.

9. The method of claim 1, wherein the second pressure is more than 30 mTorr higher than the first pressure.

10. The method of claim 1, wherein the second bias power is more than 50 W lower than the first bias power.

11. The method of claim 1, wherein the over-etch and the plasma oxidation processes further comprise performing an O₂ flushing process.

12. The method of claim 1, wherein patterning the polysilicon layer comprises:
first-etching the polysilicon layer to a first etch stop point determined based on an etch degree of a region where an isolation pattern is formed; and
second-etching the polysilicon layer to a second etch stop point set based on an etch degree of a region where a dense pattern is formed;
wherein the first-etching process is performed in a lower pressure than the second-etching process in a range of the first pressure.

13. The method of claim 12, wherein the first-etching process uses a gas mixture of HeO and hydro bromide (HBr).

14. The method of claim 12, wherein the second-etching process uses a gas mixture of He, HBr, and O₂.

15. The method of claim 1, wherein the polysilicon layer includes an N-doped polysilicon layer in an N-type metal oxide silicon (MOS) region and a P-type doped polysilicon layer in a PMOS region.

16. The method of claim 1, further comprising performing an annealing process after forming the polysilicon layer.

17. The method of claim 1, wherein patterning the polysilicon layer and performing the over-etch process and the plasma oxidation process are executed in-situ.
